(19) United States
(12) Patent Application Publication
(10) Pub. No.: US 2020/0044093 A1
(43) Pub. Date: Feb. 6, 2020

(54) Thin Film Transistor and Manufacturing Method Thereof, Array Substrate

(71) Applicants: Hefei Xinsheng Optoelectronics Technology Co., Ltd., Anhui (CN); BOE Technology Group Co., Ltd., Beijing (CN)

(72) Inventors: Jun Liu, Beijing (CN); Bin Zhou, Beijing (CN); Tongshang Su, Beijing (CN); Wei Song, Beijing (CN); Wei Li, Beijing (CN); Biao Luo, Beijing (CN); Chaowei Hao, Beijing (CN)

(73) Assignees: Hefei Xinsheng Optoelectronics Technology Co., Ltd., Anhui (CN); BOE Technology Group Co., Ltd., Beijing (CN)

(21) Appl. No.: 16/398,668

(22) Filed: Apr. 30, 2019

(30) Foreign Application Priority Data
Aug. 1, 2018 (CN) 201810862119.8

(51) Int. Cl. H01L 29/786; H01L 29/49; H01L 29/66; H01L 27/12

(52) U.S. Cl. CPC H01L 29/78633; H01L 29/4908; H01L 27/1218; H01L 27/124; H01L 29/66757

(57) ABSTRACT

A thin film transistor and a manufacturing method thereof, and an array substrate are provided. The thin film transistor includes an active layer, a source electrode, a drain electrode, a gate electrode, and a light shielding portion. The source electrode and the drain electrode electrically connect to the active layer, respectively, the gate electrode and the light shielding portion are on same one side of the active layer; in a direction from the source electrode to the drain electrode, the gate electrode is between the source electrode and the drain electrode, and the light shielding portion is at at least one of a group consisting of a spacing between the gate electrode and the source electrode and a spacing between the gate electrode and the drain electrode.

### CROSS REFERENCE TO RELATED APPLICATIONS

The present application claims priority of Chinese Patent Application No. 201810862119.8 filed on Aug. 1, 2018, the disclosure of which is incorporated herein by reference in its entirety as part of the present application.

### TECHNICAL FIELD

At least one embodiment of the present disclosure relates to a thin film transistor and a manufacturing method thereof, an array substrate.

### BACKGROUND

In the case where the active layer of a thin film transistor is exposed to light, a large number of photo-generated carriers are generated, thereby possibly generating a leakage current. The leakage current adversely affects the electrical properties of the thin film transistor and the performances of electronic products including the thin film transistor. For example, in the case where a thin film transistor is applied in an electronic display product, for example, as a switching element of a pixel unit of the electronic display product, after the active layer of the thin film transistor is irradiated with light, the leakage current of the thin film transistor in a turn-off state is increased, this can result in defects such as an afterimage and a crosstalk of the electronic display product.

### SUMMARY

At least one embodiment of the present disclosure provides a thin film transistor, the thin film transistor comprises an active layer, a source electrode, a drain electrode, a gate electrode, and a light shielding portion. The source electrode and the drain electrode electrically connect to the active layer, respectively; the gate electrode and the light shielding portion are on same one side of the active layer. In a direction from the source electrode to the drain electrode, the gate electrode is between the source electrode and the drain electrode; and the light shielding portion is at at least one of a group consisting of a spacing between the gate electrode and the source electrode and a spacing between the gate electrode and the drain electrode.

For example, in the thin film transistor provided by at least one embodiment of the present disclosure, the light shielding portion is made of an insulation material.

For example, in the thin film transistor provided by at least one embodiment of the present disclosure, the light shielding portion is formed through oxidization of a local region of a film layer that has same one material as the gate electrode.

For example, in the thin film transistor provided by at least one embodiment of the present disclosure, in a direction perpendicular to a plane on which the active layer is located, a thickness of the light shielding portion is smaller than a thickness of the gate electrode.

For example, in the thin film transistor provided by at least one embodiment of the present disclosure, in a direction that is parallel to a plane on which the active layer is located and along the direction from the source electrode to the drain electrode, a width of the light shielding portion ranges from ¼ to ½ of a width of the gate electrode.

For example, in the thin film transistor provided by at least one embodiment of the present disclosure, the gate electrode comprises a metal material, and the light shielding portion comprises a metal oxide corresponding to the metal material.

For example, in the thin film transistor provided by at least one embodiment of the present disclosure, the gate electrode comprises a copper or a copper alloy, and the metal oxide comprises a copper oxide; or, the gate electrode comprises a silver or a silver alloy, and the metal oxide comprises a silver oxide.

For example, in the thin film transistor provided by at least one embodiment of the present disclosure, the active layer comprises a channel region and two conductorized regions respectively at two sides of the channel region; the source electrode and the drain electrode electrically connect to the two conductorized regions, respectively; and an orthographic projection of a combination structure of the gate electrode and the light shielding portion on a plane on which the active layer is located overlaps with an orthographic projection of the channel region on the plane on which the active layer is located.

For example, in the thin film transistor provided by at least one embodiment of the present disclosure, the thin film transistor further comprises a light shielding layer on a side, which is away from the gate electrode, of the active layer. The orthographic projection of the channel region of the active layer on the plane on which the active layer is located overlaps with an orthographic projection of the light shielding layer on the plane on which the active layer is located.

For example, in the thin film transistor provided by at least one embodiment of the present disclosure, the thin film transistor further comprises a gate insulation layer between the active layer and the gate electrode. The orthographic projection of the combination structure of the gate electrode and the light shielding portion on the plane on which the active layer is located overlaps with an orthographic projection of the gate insulation layer on the plane on which the active layer is located.

For example, in the thin film transistor provided by at least one embodiment of the present disclosure, the thin film transistor further comprises a gate insulation layer located between the active layer and the gate electrode. An orthographic projection of a combination structure of the gate electrode and the light shielding portion on a plane on which the active layer is located overlaps with an orthographic projection of the gate insulation layer on a plane on which the active layer is located.

At least one embodiment of the present disclosure provides an array substrate, and the array substrate comprises a thin film transistor. The thin film transistor comprises an active layer, a source electrode, a drain electrode, a gate electrode and a light shielding portion; the source electrode and the drain electrode electrically connect to the active layer, respectively; the gate electrode and the light shielding portion are on same one side of the active layer; in a direction from the source electrode to the drain electrode, the gate electrode is between the source electrode and the drain electrode; and the light shielding portion is at at least one of a group consisting of a spacing between the gate electrode and the source electrode and a spacing between the gate electrode and the drain electrode.

At least one embodiment of the present disclosure provides a manufacturing method of a thin film transistor, and the manufacturing method comprises: forming an active layer; forming a gate electrode and a light shielding portion on same one side of the active layer; and forming a source electrode and a drain electrode that electrically connect to the active layer, respectively. In a direction from the source electrode to the drain electrode, the gate electrode is formed between the source electrode and the drain electrode; and the light shielding portion is formed at at least one of a group consisting of a spacing between the gate electrode and the source electrode and a spacing between the gate electrode and the drain electrode.

For example, in the manufacturing method provided by at least one embodiment of the present disclosure, a material of the light shielding portion is an insulation material.

For example, in the manufacturing method provided by at least one embodiment of the present disclosure, the gate electrode and the light shielding portion are formed from a same film layer by performing a light shielding treatment on the same film layer.

For example, in the manufacturing method provided by at least one embodiment of the present disclosure, forming of the gate electrode and the light shielding portion comprises: forming a conductive material thin film and forming a photoresist layer on the conductive material thin film; patterning the photoresist layer to form a first photoresist pattern, and patterning the conductive material thin film by taking the first photoresist pattern as a first mask, so as to form a first conductive layer; removing a portion of the first photoresist pattern to form a second photoresist pattern and allowing a side edge of the first conductive layer to be exposed; performing an oxidizing treatment to the first conductive layer, in which the side edge, that is not covered by the second photoresist pattern, of the first conductive layer is oxidized and forms the light shielding portion, and a portion, which is not oxidized, of the first conductive layer forms the gate electrode; and removing the second photoresist pattern.

For example, in the manufacturing method provided by at least one embodiment of the present disclosure, forming of the gate electrode and the light shielding portion further comprises: processing the photoresist layer with a halftone mask to allow the first photoresist pattern to comprises a first portion and a second portion, in which a thickness of the first portion is smaller than a thickness of the second portion; and performing a thickness reduction process on the first photoresist pattern to remove a portion of the first photoresist pattern, in which the first portion is removed to allow a portion, which overlaps the first portion, of the first conductive layer to be exposed after the first portion is removed and to be thinned, and the second portion forms the second photoresist pattern.

For example, in the manufacturing method provided by at least one embodiment of the present disclosure, a material used to form the first conductive layer comprises a metal material; and performing of the oxidizing treatment to the first conductive layer comprises: oxidizing a portion, that is not covered by the second photoresist pattern, of the first conductive layer to form a metal oxide by an oxygen ion implantation or an oxygen implantation.

For example, in the manufacturing method provided by at least one embodiment of the present disclosure, the manufacturing method further comprises: forming an insulation material thin film on a side of the active layer before forming the conductive material thin film; and patterning the insulation material film to form the gate insulation layer by taking the first photoresist pattern and the first conductive layer as a second mask, in which an orthographic projection of the first conductive layer on a plane on which the active layer is located overlaps with an orthographic projection of the gate insulation layer on the plane on which the active layer is located.

### BRIEF DESCRIPTION OF THE DRAWINGS

In order to clearly illustrate the technical solutions of the embodiments of the present disclosure, the accompanying drawings in the embodiments of the present disclosure will be introduced briefly in the following. It is apparent that the described drawings are only related to some embodiments of the disclosure and thus are not limitative of the disclosure.

FIG. 1A is a plan view of a thin film transistor according to some embodiments of the present disclosure;

FIG. 1B is a cross-sectional view, along line A-B, of the thin film transistor as illustrated in

FIG. 1A;

FIG. 2 is a cross-sectional view of another thin film transistor according to some embodiments of the present disclosure;

FIG. 3 is a cross-sectional view of an array substrate provided by some embodiments of the present disclosure; and

FIG. 4A-FIG. 4H are schematic diagrams illustrating manufacturing process of a manufacturing method of a thin film transistor according to some embodiments of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is apparent that the described embodiments are just a part but not all of the embodiments of the disclosure. Based on the described embodiments herein, those skilled in the art may obtain other embodiment, without any creative work, which shall be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

For example, in an electronic display device (for example, a liquid crystal display device or an organic light emitting diode display device) including a thin film transistor as a switching element of a pixel unit, a large number of metal structures such as signal lines are usually disposed. These metal structures can reflect part of light emitted from the electronic display device or be incident from outside of the electronic display device, so that the part of the light is reflected and incident on the active layer of the thin film transistor, this adversely affects the electrical performance of the thin film transistor. Although the gate electrode of the thin film transistor can block part of the light that is incident on the active layer, however, in an actual manufacturing process, in order to prevent the gate electrode from contacting other structures such as a source electrode, a drain electrode, and the like, the size of the gate electrode is limited, so that the irradiation of light on the active layer is hard to be further reduced.

At least one embodiment of the present disclosure provides a thin film transistor, the thin film transistor comprises an active layer, a source electrode, a drain electrode, a gate electrode, and a light shielding portion. The source electrode and the drain electrode are respectively electrically connected to the active layer, the gate electrode and the light shielding portion are located on a same side of the active layer, in a direction from the source electrode to the drain electrode, the gate electrode is located between the source electrode and the drain electrode, and the light shielding portion is located at at least one of a spacing between the gate electrode and the source electrode and a spacing between the gate electrode and the drain electrode (at least one of the group consisting of a spacing between the gate electrode and the source electrode and a spacing between the gate electrode and the drain electrode), that is, the light shielding portion is located between the gate electrode and the source electrode and/or between the gate electrode and the drain electrode. For example, the thin film transistor may include a base substrate, and the above-mentioned structures may be disposed on the base substrate. For example, the gate electrode and the light shielding portion are located on the side of the active layer away from the base substrate. In the thin film transistor, the light shielding portion can block the light that is from the side of the active layer away from the base substrate and propagated toward the active layer. Compared with the case where only the gate electrode is disposed in the thin film transistor (the case where only the gate electrode serves as a light-shielding structure), light illumination on the active layer is further reduced or prevented, an adverse effect of the light illumination on an electrical performance of the thin film transistor is reduced, and the electrical performance of the thin film transistor is improved.

For example, the light shielding portion is located between the gate electrode and the source electrode means that the light shielding portion is located between the gate electrode and the portion, which is in the same plane as the light shielding portion, of the source electrode, and the light shielding portion is located between the gate electrode and the drain electrode means that the light shielding portion is located between the gate electrode and the portion, which is in the same plane as the light shielding portion, of the drain electrode.

In one example, the orthographic projection of the source electrode on the plane where the light shielding portion is located does not overlap (for example, does not overlap but connects) the light shielding portion, and the orthographic projection of the drain electrode on the plane where the light shielding portion is located does not overlap (for example, does not overlap but connects) the light shielding portion.

In another example, the orthographic projection of the source electrode on the plane where the light shielding portion is located overlaps the light shielding portion, and the orthographic projection of the drain electrode on the plane where the light shielding portion is located overlaps the light shielding portion.

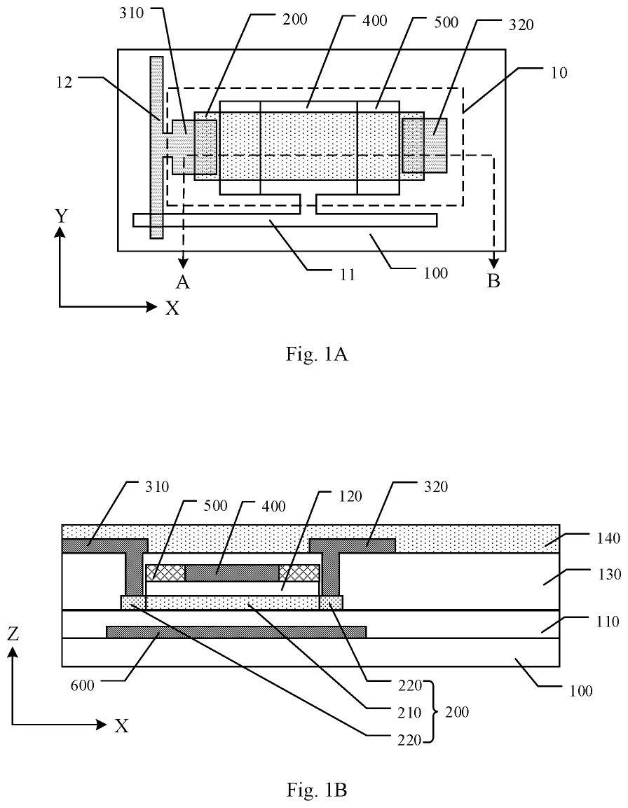

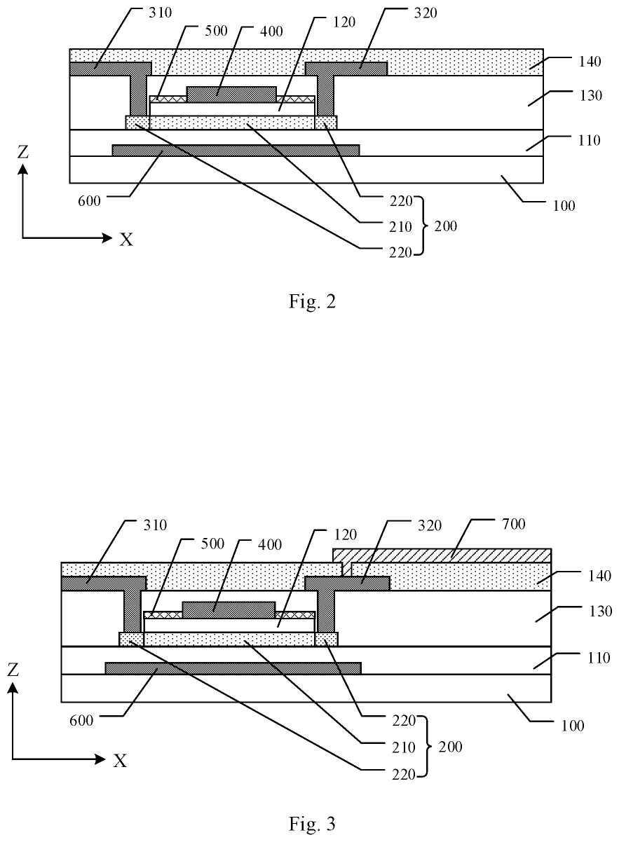

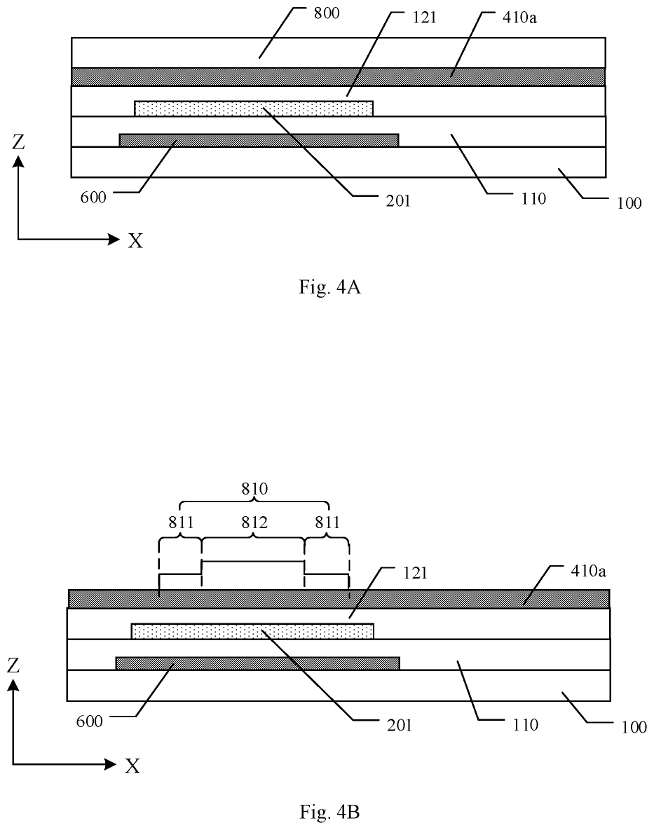

It should be noted that, in at least one embodiment of the present disclosure, the light transmittance of the light shielding portion is not limited as long as the light shielding portion can significantly reduce the intensity of the light that is propagated toward the active layer. For example, the light transmittance of the light shielding portion is less than 50%, such as less than 25%, and for example, less than 10%. For example, in at least one example, the light transmittance of the light shielding portion is close to or equal to 0%. It should be noted that, in at least one embodiment of the present disclosure, the effect of the light shielding portion in reducing the intensity of the light that is that is propagated toward the active layer is compared with a structure disposed at a same position in a related thin film transistor. Illustratively, taking the thin film transistor of FIG. 1B in the following embodiments as an example, in the case where the light shielding portion 500 is not disposed, the spacing in which the light shielding portion 500 is located is filled with an interlayer dielectric layer 130. Thus, the light shielding portion 500 can have an effect of reducing the intensity of light that is propagated toward the active layer as long as the light transmittance of the material of the light shielding portion 500 is smaller than the light transmittance of the material of the interlayer dielectric layer 130.

Hereinafter, the technical solution in at least one embodiment of the present disclosure is described by taking the case where the light transmittance of the light shielding portion is equal to 0% as an example.

In the thin film transistor provided by at least one embodiment of the present disclosure, the relative position between the source electrode, the drain electrode, and the active layer is not limited as long as the source electrode and the drain electrode can be respectively electrically connected to the active layer. For example, in some embodiments of the present disclosure, the source electrode and the drain electrode are located on the side of the active layer away from the base substrate. For another example, in other embodiments of the present disclosure, the source electrode and the drain electrode are located between the active layer and the base substrate.

Hereinafter, the thin film transistor in at least one embodiment of the present disclosure is described by taking the source electrode and the drain electrode on the side of the active layer away from the base substrate as an example. In a manufacturing process of the thin film transistor, the active layer is formed before the source electrode and the drain electrode, such that the formation of the active layer is not affected by a step difference caused by a formation of the source electrode and the drain electrode, and the flatness of the active layer can be improved, thereby the electrical performance of the thin film transistor is improved.

It should be noted that, in the case where the source electrode and the drain electrode in the thin film transistor are located on the side of the active layer away from the base substrate, in a manufacturing process of the thin film transistor, large spacing are disposed between the gate electrode and the source electrode and between the gate electrode and the drain electrode, so as to avoid electrical contact between the gate electrode and the source electrode and between the gate electrode and the drain electrode. For example, in at least one embodiment of the present disclosure, the light shielding portion is an insulation layer (that is, the light shielding portion is made of an insulation material). Thus, the light shielding portion can be disposed to occupy at least a portion of the spacing, and even if the light shielding portion fills the spacing, the gate electrode, the source electrode and the drain electrode are not electrically connected. Thus, providing of the light shielding portion does not adversely affect the design size of the gate electrode (for example, the design size is reduced).

Hereinafter, a thin film transistor and a manufacturing method thereof, and an array substrate according to at least one embodiment of the present disclosure is described with reference to the accompanying drawings, and in the case where it is not clearly stated, the light shielding portion in the following embodiments of the present disclosure is an insulation layer.

FIG. 1A is a plan view of a thin film transistor according to some embodiments of the present disclosure, and FIG. 1A is a structural view of part of the thin film transistor; and FIG. 1B is a cross-sectional view, along line A-B, of the thin film transistor as illustrated in FIG. 1A.

For example, in at least one embodiment of the present disclosure, as illustrated in FIG. 1A and FIG. 1B, a thin film transistor 10 (portion in the dashed box in FIG. 1A) includes a base substrate 100, and an active layer 200, a source electrode 310, a drain electrode 320, a gate electrode 400, a light blocking portion 500 which are located on the base substrate 100. The source electrode 310 and the drain electrode 320 are respectively electrically connected to the active layer 200, the gate electrode 400 and the light shielding portion 500 are located on the side of the active layer 200 away from the base substrate 100, that is, the thin film transistor 10 is a top-gate type thin film transistor. In the direction from the source electrode 310 to the drain electrode 320, the gate electrode 400 is located between the source electrode 310 and the drain electrode 320, the light blocking portions 500 are respectively disposed between the gate electrode 400 and the source electrode 310 and between the gate electrode 400 and the drain electrode 320. The gate electrode 400 and the light blocking portion 500 are located in a same layer. The light that is incident from the side of the active layer 200 away from the base substrate 100 is blocked by both of the gate electrode 400 and the light shielding portion 500, this increases a light shielding area for the active layer 200, thereby reducing the number of carriers generated by the active layer 200 due to light illumination, or avoiding the active layer 200 being illuminated so that no carrier is generated, and therefore, the adverse effects of light illumination on the electrical performance of the thin film transistor are reduced or eliminated, and the electrical performance of the thin film transistor is improved.

For example, in at least one embodiment of the present disclosure, as illustrated in FIG. 1A, a first signal line 11 connected to the gate electrode 400 and a second signal line 12 connected to the source electrode 310 are disposed on the base substrate 100. By applying a voltage to the gate electrode 400 and the source electrode 310 respectively through the first signal line 11 and the second signal line 12, the electrical function of the thin film transistor can be controlled. For example, the state (in turning-on state or in turning-off state) of the thin film transistor can be controlled and the value of the output voltage (the voltage of the drain electrode 320) of the thin film transistor in a turning-on state can be adjusted. For example, in at least one embodiment of the present disclosure, the thin film transistor may be applied in an array substrate, and correspondingly, the first signal line 11 may be a gate line, and the second signal line 12 may be a data line.

For example, in at least one embodiment of the present disclosure, in the direction (that is the direction along the X-axis as illustrated in FIG. 1A and FIG. 1B) that is parallel to the plane on which the base substrate is located, only one side of the gate electrode may be provided with the light shielding portion; or two sides of the gate electrode may be provided with the light shielding portion.

Hereinafter, the technical solutions in at least one of the following embodiments are described by taking the case, that two sides of the gate electrode 400 are provided with the light shielding portion 500, as illustrated in FIG. 1A and FIG. 1B as an example.

In at least one embodiment of the present disclosure, a spatial rectangular coordinate system is established by taking the base substrate as a reference, so as to explain the position of each component in the thin film transistor. For example, in the spatial rectangular coordinate system, as illustrated in FIG. 1A and FIG. 1B, the directions of the X-axis and the Y-axis (not illustrated) are parallel to the plane on which the base substrate 100 is located, and the direction along the Z-axis is perpendicular to the plane on which the base substrate 100 is located, and the direction along the X-axis is parallel to the direction from the source electrode 310 to the drain electrode 320 (the direction where the source electrode 310 to the drain electrode 320 are parallelly arranged). For example, in at least one embodiment of the present disclosure, the plane on which the active layer 200 is located is parallel to the plane on which the base substrate 100 is located.

In at least one embodiment of the present disclosure, the relationship between the manufacturing methods of the gate electrode and the light shielding portion in the thin film transistor is not limited.

For example, in some embodiments of the present disclosure, the gate electrode and the light shielding portion may be separately provided. That is, the gate electrode and the light shielding portion may be formed separately in different processes, and the gate electrode and the light shielding portion may be connected to each other or may be spaced apart from each other. In this case, there is no connection between the material for forming the gate electrode and the material for forming the light shielding portion, and the materials for forming the gate electrode and the light shielding portion may be separately selected according to actual needs (for example, process conditions), and therefore, the selection range for the materials for forming the gate electrode and the light shielding portion is increased. For example, the material of the gate electrode is a conductive material, for example, a light-shielding conductive material; and the material of the light shielding portion is an insulation material having a light blocking function (light shielding function).

For example, the gate electrode and the light shielding portion may be separately disposed. The material of the gate electrode may include (or may be) a copper-based metal such as copper (Cu), copper-molybdenum alloy (Cu/Mo), copper-titanium alloy (Cu/Ti), copper-molybdenum-titanium alloy (Cu/Mo/Ti), copper-molybdenum-tungsten alloy. (Cu/Mo/W), copper-molybdenum-niobium alloy (Cu/Mo/Nb), or the like; the material of the gate electrode may also include (or may also be) a chromium-based metal such as chromium-molybdenum alloy (Cr/Mo), chromium-titanium alloy (Cr/Ti), chromium-molybdenum-titanium alloy (Cr/Mo/Ti), or the like; and the material of the gate electrode may also include (or may also be) aluminum, aluminum alloy, or the like. The material of the light shielding portion may include (or may be) a black organic material such as a black resin or the like, and may also include (or may also be) a black inorganic material such as copper oxide, silver oxide, or the like.

For example, in other embodiments of the present disclosure, the gate electrode and the light shielding portion are formed by patterning and processing a same film layer in a same process, thereby the gate electrode and the light shielding portion can be formed in a same layer. In an actual process, due to the limitation of a manufacturing process precision, corners are formed at the edges of components (for example, gate electrodes and the like) of the thin film transistor due to a residue. Excessive corners can adversely affect the manufacturing process of thin film transistors (for example, generating parasitic capacitance, step difference, and the like), and therefore, the electrical performance of thin film transistor can be adversely affected. In the case where the gate electrode and the light shielding portion are formed from a same film layer in a same process, compared with the case where the gate electrode and the light shielding portion are separately formed, there is no interface problem between the gate electrode and the light shielding portion, no overlap between the gate electrode and the light shielding portion presents in the connection region of the gate electrode and the light shielding portion, that is, no corner presents between the gate electrode and the light shielding portion for the case where the gate electrode and the light shielding portion are formed from a same film layer in a same process, and thus, the electrical performance of the thin film transistor can be improved.

In at least one embodiment of the present disclosure, in the case where the gate electrode and the light shielding portion are formed from a same film layer in a same process, the film layer may include (for example, may be) a conductive material, and the conductive material can be converted into an insulation material after the conductive material is processed. In at least one embodiment of the present disclosure, the types of manufacturing processes for converting the conductive material into the insulation material is not limited, and the types of manufacturing processes may be selected according to specific type of the conductive material. For example, in a thin film transistor provided by at least one embodiment of the present disclosure, the above-mentioned manufacturing process of converting the conductive material into the insulation material may be an oxidation process, and the gate electrode and the light shielding portion are formed from a same film layer by performing local oxidation of the same film layer. For example, the light shielding portion is formed by performing local oxidation to a film layer which has a same material as the gate electrode. For example, the oxidized portion of the film layer forms the light shielding portion, and the non-oxidized portion of the film layer forms the conductive gate electrode.

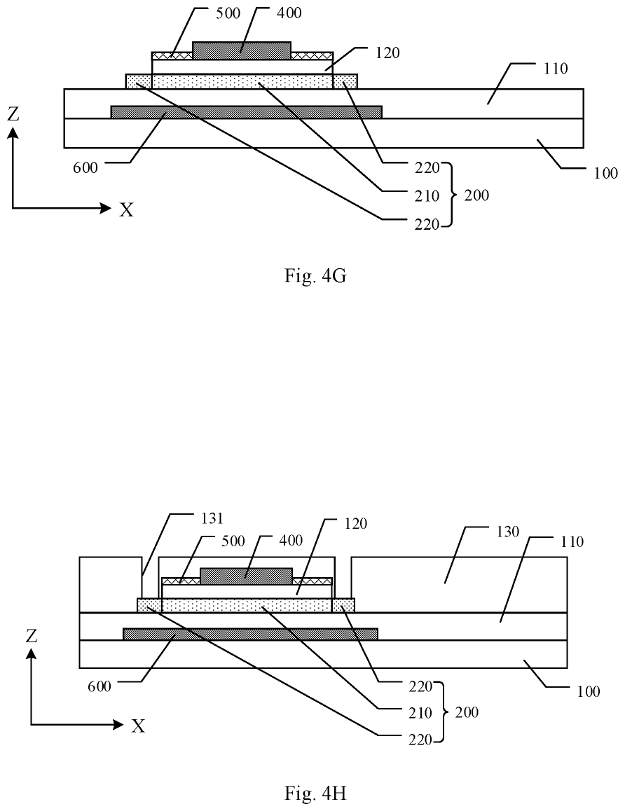

It should be noted, specific processes of forming the gate electrode and the light shielding portion by performing local oxidation to the same film layer can refer to the following description of embodiments of a manufacturing method of a thin film transistor (for example, the embodiments as illustrated in FIG. 4A to FIG. 4H), and thus specific processes are not described here.

For example, in the thin film transistor provided by at least one embodiment of the present disclosure, the gate electrode and the light shielding portion are formed from a same film layer in a same process. The gate electrode includes (is) a metal material, and the light shielding portion includes (is) one oxide or more oxides corresponding to the metal material. For example, in the thin film transistor provided by at least one embodiment of the present disclosure, the gate electrode includes (is) copper or copper alloy, silver or silver alloy, and the oxide includes (is) copper oxide, silver oxide. Because both of the copper oxide and the silver oxide are black metal oxides, the light shielding performance of the light shielding portion can be improved.

In the thin film transistor provided by at least one embodiment of the present disclosure, in the case where the gate electrode and the light shielding portion are formed from a same film layer in a same process, the thicknesses of the gate electrode and the light shielding portion are not limited, and can be designed according to the specific manufacturing process adopted.

For example, in some embodiments of the present disclosure, as illustrated in FIG. 1A and FIG. 1B, in the direction along the Z-axis, the thickness of the gate electrode 400 and the thickness of the light shielding portion 500 are the same (including substantially the same), and in this case, the manufacturing process of the gate electrode 400 and the light shielding portion 500 can be simplified.

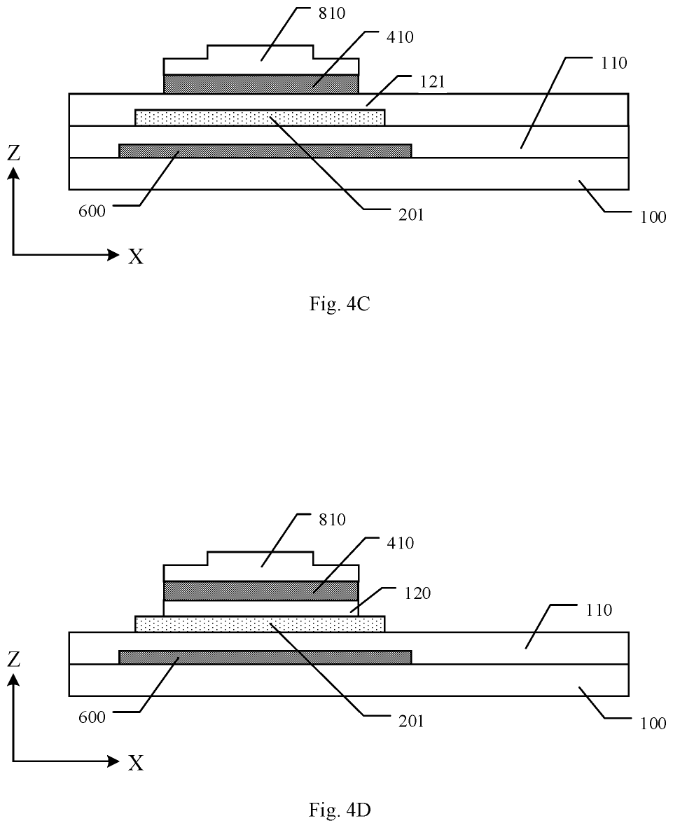

FIG. 2 is a cross-sectional view of another thin film transistor according to some embodiments of the present disclosure.

For example, in the thin film transistor provided by other embodiments of the present disclosure, in the direction perpendicular to the plane on which the base substrate is located, the thickness of the light shielding portion is smaller than the thickness of the gate electrode. Illustratively, as illustrated in FIG. 2, the thickness of the light shielding portion 500 is smaller than the thickness of the gate electrode 400 in the direction along the Z-axis, and in this case, the processing difficulty of the light shielding portion 500 can be reduced while ensuring the gate electrode 400 to have a sufficient thickness. For example, in the process of locally oxidizing a film layer to obtain the light shielding portion 500, the portion, which is corresponding to the light shielding portion 500 to be formed, of the film layer may be completely oxidized and converted into an insulation material, and thus the risk of having residual conductive material in the light shielding portion 500 can be reduced, thereby preventing the gate electrode 400 from electrically connecting to the source electrode 310 or the drain electrode 320.

For example, in at least one embodiment of the present disclosure, in the case where the thickness of the light shielding portion is smaller than the thickness of the gate electrode, the thickness of the light shielding portion may be ranged from 1/10 to ¼ (for example, ⅕) of the thickness of the gate electrode. For example, the thickness of the gate electrode ranges from 200 to 700 nm, for example, 400 nm, 600 nm, or the like; and the thickness of the light shielding portion ranges from 20 to 150 nm, for example, 40 nm, 80 nm, 100 nm, or the like. The specific thicknesses of the gate electrode and the light shielding portion may be designed according to adopted materials, and the specific thicknesses of the gate electrode and the light shielding portion are not limited to the above-mentioned parameter ranges. For example, for the gate electrode and the light shielding portion having the parameters within the above-mentioned parameter ranges, the material of the gate electrode may be copper, and the material of the light shielding portion may be copper oxide (CuOₓ).

In the thin film transistor provided by at least one embodiment of the present disclosure, the width of the light shielding portion in the direction from the source electrode to the drain electrode is not limited as long as the width of the light shielding portion does not adversely affect the performance or manufacturing process of the thin film transistor. For example, in the thin film transistor provided by at least one embodiment of the present disclosure, in the direction parallel to the plane on which the base substrate is located and along the direction from the source electrode to the drain electrode, the width of the light shielding portion ranges from ¼ to ½ of the width of the gate electrode. Illustratively, as illustrated in FIG. 1A and FIG. 1B and FIG. 2, in the direction along the X-axis, the width of the gate electrode 400 may range from 4-6 microns, for example, 4.5 microns, 5 microns, 5.5 microns, or the like; and the width of the light shielding portion 500 may range from 1 to 3 microns, for example, 1.5 microns, 2 microns, 2.5 microns, or the like.

For example, in at least one embodiment of the present disclosure, the material of the active layer may be amorphous silicon, polycrystalline silicon, oxide semiconductor, or the like. For example, the oxide semiconductor may be a metal oxide such as indium gallium zinc oxide (IGZO), indium zinc oxide (IZO), zinc oxide (ZnO), gallium zinc oxide (GZO), or the like. For example, the thickness of the active layer may range from 0.05 to 0.1 microns.

For example, in the thin film transistor provided by at least one embodiment of the present disclosure, the active layer may include a channel region and source-drain contact regions located, for example, at two sides of the channel region. The source-drain contact regions are, for example, conductorized regions (that is, the regions that are processed to have a conductive property) or include ohmic contact layers, and the source electrode and the drain electrode are electrically connected to the source-drain contact regions.

Illustratively, as illustrated in FIG. 1A, FIG. 1B, and FIG. 2, the active layer 200 is a polysilicon layer, and includes two conductorized regions 220 electrically connected to the source electrode 310 and the drain electrode 320 respectively and a channel region 210 between the two conductorized regions 220. The conductorized regions of the active layer 200 may be formed by allowing part of the active layer 200 to be converted into a conductor, and the portion, which is not converted into a conductor, of the active layer 200 forms the channel region 210. For example, the process for converting the polysilicon layer into a conductor may be an ion doping process. For example, in at least one embodiment of the present disclosure, the orthographic projection of the combination structure of the gate electrode and the light-shielding portion on the base substrate overlaps (for example, completely overlaps) with the orthographic projection of the channel region on the base substrate. In this case, in a manufacturing process of the thin film transistor, the process of converting part of a semiconductor film layer into a conductor is conducted by taking both of the gate electrode and the light shielding portion as a mask, thereby forming the active layer 200 including the channel region 210 and the conductorized region 220.

For example, the thin film transistor provided in at least one embodiment of the present disclosure further includes a gate insulation layer between the active layer and the gate electrode. For example, the orthographic projection of the gate electrode and the light shielding portion on the base substrate overlaps with the orthographic projection of the gate insulation layer on the base substrate. Illustratively, as illustrated in FIG. 1A, FIG. 1B, and FIG. 2, the gate insulation layer 120 is located between the gate electrode 400 and the active layer 200. In a manufacturing process of the thin film transistor (for example, in the process of pattering a layer for forming the gate insulation layer 120), the gate insulation layer 120 may be formed by taking the gate electrode and the light shielding portion as a mask. In this case, in the process of forming the active layer 200 from a semiconductor film layer through a treatment for forming a conductor, the gate insulation layer 120 does not hinder (cause an adverse impact on) the process of converting part of the semiconductor film layer into a conductor, such as ion doping or the like.

For example, in at least one embodiment of the present disclosure, the material of the gate insulation layer may include (for example, may be) silicon nitride (SiNx), silicon oxide (SiOx), aluminum oxide (Al₂O₃), aluminum nitride (AlN), or other suitable materials. For example, the thickness of the gate insulation layer may range from 0.1 to 0.2 microns.

For example, in at least one embodiment of the present disclosure, the thin film transistor further includes a light shielding layer located between the active layer and the base substrate, and the orthographic projection of the channel region of the active layer on the base substrate overlaps with the orthographic projection of the light shielding layer on the base substrate. Illustratively, as illustrated in FIG. 1A, FIG. 1B and FIG. 2, A light shielding layer 600 is disposed between the base substrate 100 and the active layer 200, and the light shielding layer 600 at least partially overlaps the channel region 210 of the active layer 200. Thus, in the case where the base substrate 100 is a transparent substrate or a half-transparent substrate, the light shielding layer 600 can block light that is incident from the side of the base substrate 100 away from the active layer 200, thereby reducing the number of photogenerated carriers caused by the light illuminating the active layer 200, and thus the electrical performance of the thin film transistor is improved.

For example, in the thin film transistor provided by at least one embodiment of the present disclosure, the orthographic projection of the channel region of the active layer on the base substrate overlaps with the orthographic projection of the light shielding layer on the base substrate or within the orthographic projection of the light shielding layer on the base substrate. For example, the orthographic projection of the active layer on the base substrate overlaps with the orthographic projection of the light-shielding layer on the base substrate or within the orthographic projection of the light-shielding layer on the base substrate. In this case, the light shielding area of the light shielding layer for the active layer can be increased, and the electrical performance of the thin film transistor can be further improved. For example, in at least one embodiment of the present disclosure, along the direction from the source electrode to the drain electrode, the width of the channel region of the active layer ranges from 8 to 10 microns, and the width of the light shielding layer ranges from 12 to 18 microns.

For example, in at least one embodiment of the present disclosure, the material of the light shielding layer may include (for example, may be) a non-transparent material such as metal, black resin, or the like. For example, the material of the light shielding layer may include (for example, may be) molybdenum, molybdenum-niobium alloy or the like, and the thickness of the light-shielding layer may range from 0.1 to 0.2 microns, for example, 0.12 microns, 0.15 microns, 0.18 microns, or the like.

It should be noted that, in at least one embodiment of the present disclosure, the type of the thin film transistor is not limited. For example, in some embodiments of the present disclosure, as illustrated in FIG. 1A, FIG. 1B, and FIG. 2, the thin film transistor is a top-gate type thin film transistor, and in this case, a light shielding layer 600 may be disposed in the thin film transistor. For example, in other embodiments of the present disclosure, the thin film transistor is a dual-gate thin film transistor, the gate electrode located on the side of the active layer away from the base substrate is a first gate electrode, and a second gate electrode is disposed between the active layer and the base substrate, and in this case, it is not necessary to dispose the light shielding layer 600 as illustrated in FIG. 1B and FIG. 2 in the thin film transistor. For example, in the direction parallel to the plane on which the base substrate is located, the size of the second gate electrode and the relative positional relationship between the second gate electrode and the active layer can refer to the size of the light shielding layer and the relative positional relationship between the gate electrode and the light shielding layer in the above-mentioned embodiments, which is not described here.

For example, in the thin film transistor provided by at least one embodiment of the present disclosure, as illustrated in FIG. 1A, FIG. 1B, and FIG. 2, a buffer layer 110 may be disposed between the base substrate 100 and the active layer 200. For example, in the case where the light shielding layer 600 is disposed on the base substrate 100, the buffer layer 110 may be located between the light shielding layer 600 and the active layer 200. The buffer layer 120 can prevent ions or the like in the base substrate 100 or the light shielding layer 600 from intruding into the active layer 200, for example, can prevent the active layer 200 from being contaminated by sodium ions or the like from the base substrate 100, thereby ensuring the electrical performance of the thin film transistor.

For example, in at least one embodiment of the present disclosure, the material of the buffer layer may include silicon oxide (SiOx), silicon nitride (SiNx), silicon oxynitride (SiOxNy), or the like. For example, the buffer layer may be a single layer structure composed of silicon nitride or silicon oxide, or a two-layer structure composed of silicon nitride and silicon oxide. For example, the thickness of the buffer layer may range from 0.3 to 0.5 microns.

For example, in the thin film transistor provided by at least one embodiment of the present disclosure, as illustrated in FIG. 1A, FIG. 1B, and FIG. 2, an interlayer dielectric layer 130 may be disposed between the gate electrode 400 and the source-drain electrode layer (including a source electrode 310 and a drain electrode 320). Via-holes are disposed in the interlayer dielectric layer 130, and the source electrode 310 and the drain electrode 320 are electrically connected to the active layer 200 through the via-holes.

For example, in at least one embodiment of the present disclosure, the interlayer dielectric layer may be a single layer structure or a multilayer structure with two or more layers. For example, the interlayer dielectric layer may include (for example, may be) silicon nitride, silicon oxide, silicon oxynitride, or the like. For example, the thickness of the interlayer dielectric layer may range from 0.3 to 0.5 microns.

For example, in the thin film transistor provided by at least one embodiment of the present disclosure, as illustrated in FIG. 1B and FIG. 2, a passivation layer 140 is disposed on the side of the source-drain electrode layer (including a source electrode 310 and a drain electrode 320) away from the base substrate 100. For example, the passivation layer 140 may be disposed to planarize a surface of the thin film transistor, that is, the surface of the passivation layer 140 away from the base substrate 100 can be a planar surface.

In at least one embodiment of the present disclosure, the material of the passivation layer is not limited. For example, the material of the passivation layer may include (for example, may be) silicon nitride (SiNx), silicon oxide (SiOx), silicon oxynitride (SiNxOy), or other suitable materials.

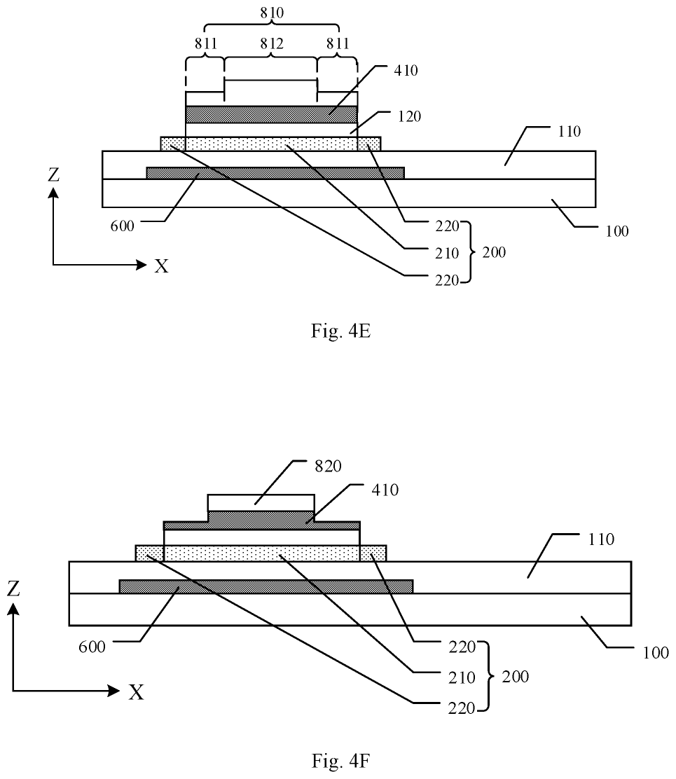

FIG. 3 is a cross-sectional view of an array substrate provided by some embodiments of the present disclosure, and FIG. 3 is a cross-sectional view of a partial region of an array substrate.

At least one embodiment of the present disclosure provides an array substrate, the array substrate includes the thin film transistor provided by any one of the above-mentioned embodiments. Exemplarily, as illustrated in FIG. 3, the array substrate includes a pixel electrode 700 on the side of the passivation layer 140 away from the base substrate 100, a via-hole is disposed in the passivation layer 140, and the pixel electrode 700 is electrically connected to the drain electrode 320 through the via-hole. For example, the gate electrode of the thin film transistor is connected to a gate line or a storage capacitor of the array substrate. For example, the source electrode of the thin film transistor is connected to a data line or a power line of the array substrate.

For example, the pixel electrode may include (for example, may be) a metal material or a transparent conductive material. For example, the transparent conductive material may include (for example, may be) indium tin oxide (ITO), indium zinc oxide (IZO), indium gallium oxide (IGO), gallium zinc oxide (GZO) zinc oxide (ZnO), indium oxide (In2O3), aluminum oxide zinc (AZO), carbon nanotubes, and the like.

At least one embodiment of the present disclosure provides a display panel including the array substrate provided by any one of the above-mentioned embodiments. In at least one embodiment of the present disclosure, no limitation will be given regarding the type of the display panel.

For example, in an example of an embodiment of the present disclosure, the display panel may be a liquid crystal display panel. The display panel may further include a color filter substrate which is opposite to the array substrate, the color filter substrate and the array substrate are opposed to each other to form a liquid crystal cell, and the liquid crystal cell is filled with a liquid crystal material. The pixel electrode and the common electrode of each pixel unit of the array substrate are used to apply an electric field to control the degree of rotation of the liquid crystal material, so as to perform a display operation.

For example, in an example of an embodiment of the present disclosure, the display panel may be an organic light emitting diode (OLED) display panel. The array substrate includes a plurality of sub-pixel regions, and a lamination including an organic light-emitting material may be formed in each of the sub-pixel regions. The pixel electrode in each of the sub-pixel regions serves as an anode or a cathode for driving the organic light-emitting material to emit light, so as to achieve a display operation.

For example, in an example of an embodiment of the present disclosure, the display panel may be an electronic paper display panel. An electronic ink layer may be formed on the array substrate of the display panel. A pixel electrode of each pixel unit is used to apply a voltage for driving charged microparticles in the electronic ink to move, so as to achieve a display operation.

For example, in at least one embodiment of the present disclosure, the display panel can be any product or component having a display function such as a television, a digital camera, a mobile phone, a watch, a tablet, a notebook, a navigator, and the like.

At least one embodiment of the present disclosure provides a manufacturing method of a thin film transistor, comprising: forming an active layer; forming both of a gate electrode and a light shielding portion on a same side of the active layer; and forming a source electrode and a drain electrode which are respectively electrically connected to the active layer. In a direction from the source electrode to the drain electrode, the gate electrode is formed between the source electrode and the drain electrode, and the light shielding portion is formed at at least one of a spacing between the gate electrode and the source electrode and a spacing between the gate electrode and the drain electrode, that is, the light shielding portion is formed between the gate electrode and the source electrode and/or between the gate electrode and the drain electrode. For example, the above-mentioned structure of the thin film transistor may be formed on a base substrate, and for example, the gate electrode and the light shielding portion may be formed on the side of the active layer away from the base substrate. In the thin film transistor obtained according to the above manufacturing method, on the side of the active layer away from the base substrate, the light shielding portion can also block the light that is propagated toward the active layer. Compared with the case where only the gate electrode is disposed in the thin film transistor (the case where only the gate electrode serves as a light-shielding structure), light irradiation on the active layer is further reduced or prevented, and the electrical performance of the thin film transistor is improved.

For example, in a manufacturing method according to at least one embodiment of the present disclosure, the material of the light shielding portion is an insulation material. Thus, in the thin film transistor obtained according to the above manufacturing method, the light shielding portion may occupy at least a portion of the spacing between the gate electrode and the drain electrode and the spacing between the source electrode and the drain electrode while ensuring the gate electrode, the source electrode and the drain electrode to be not electrically connected, thereby the design size of the gate electrode is not adversely affected.

For example, in a manufacturing method according to at least one embodiment of the present disclosure, the gate electrode and the light shielding portion are formed from a same film layer by performing a light shielding treatment with respect to a portion of the same film layer (allowing a portion of the same film layer to have a light shielding capability). In the thin film transistor obtained according to the above manufacturing method, there is no corner problem between the gate electrode and the light shielding portion, thereby the electrical performance of the thin film transistor can be improved.

For example, in a manufacturing method according to at least one embodiment of the present disclosure, forming of the gate electrode and the light shielding portion comprises: depositing a conductive material thin film and forming a photoresist layer on the conductive material thin film; patterning the photoresist layer to form a first photoresist pattern, patterning the conductive material thin film by taking the first photoresist pattern as a mask to form a first conductive layer; removing a portion of the first photoresist pattern to form a second photoresist pattern and exposing side edges of the first conductive layer (that is, allowing side edges of the first conductive layer to be not covered by the second photoresist pattern); performing an oxidizing treatment to the first conductive layer, so as to allow the side edges of the first conductive layer that is not covered by the second photoresist pattern to be oxidized and to form the light shielding portion, and to allow a non-oxidized portion of the first conductive layer to form the gate electrode; and removing the second photoresist pattern.

For example, in a manufacturing method according to at least one embodiment of the present disclosure, forming of the gate electrode and the light shielding portion further comprises: processing the photoresist layer with a halftone mask such that the first photoresist pattern comprises a first portion and a second portion, and the thickness of the first portion is e smaller than the thickness of the second portion; and performing a thickness reduction process on the first photoresist pattern to remove a portion of the first photoresist pattern. The first portion is removed and the portion of the first conductive layer overlapping the first portion is exposed (that is, not covered by the photoresist pattern after the first portion is removed) and thinned, and the second portion that is thinned forms the second photoresist pattern. In the thin film transistor obtained according to the above manufacturing method, the thickness of the light shielding portion is smaller than the thickness of the gate electrode in the direction perpendicular to the plane on which the base substrate is located. Thus, the processing difficulty of the light shielding portion can be reduced while ensuring the gate electrode to have a sufficient thickness.

For example, in a manufacturing method according to at least one embodiment of the present disclosure, the material used to form the first conductive layer comprises a metal material, performing of an oxidizing treatment to the first conductive layer comprises: oxidizing the portion of the first conductive layer not covered by the second photoresist pattern to form a metal oxide by an oxygen ion implantation or an oxygen implantation. The type of the metal material and the metal oxide may refer to the related descriptions in the above-mentioned embodiments, which is not described here.

For example, a manufacturing method according to at least one embodiment of the present disclosure further comprises: depositing an insulation material thin film on the side of the active layer before depositing the conductive material thin film; and patterning the insulation material thin film to form the gate insulation layer by using the first photoresist pattern and the first conductive layer as a mask. The orthographic projection of the first conductive layer on the plane on which the active layer is located overlaps with the orthographic projection of the gate insulation layer on the plane on which the active layer is located. Thus, in the process of forming the active layer, the gate insulation layer does not hinder the process of converting part of the semiconductor film layer into a conductor, such as ion doping or the like, such that a channel region and conductorized regions located at two sides of the channel region are formed in the active layer.

It should be noted that, in at least one embodiment of the present disclosure, The structure of the thin film transistor obtained by the above manufacturing method may be referred to the related description in the above-mentioned embodiments (for example, the embodiments as illustrated in FIG. 1A, 1B, and FIG. 2), which is not described herein.

FIG. 4A-FIG. 4H are schematic diagrams illustrating manufacturing processes of a manufacturing method of a thin film transistor according to some embodiments of the present disclosure.

Hereinafter, a manufacturing method of a thin film transistor in at least one embodiment of the present disclosure is described by taking the thin film transistor as illustrated in FIG. 2 as an example. Illustratively, as illustrated in FIG. 4A-FIG. 4H and FIG. 2, the processes of the manufacturing method of the thin film transistor are described as follows.

As illustrated in FIG. 4A, the manufacturing method of the thin film transistor comprises: providing a base substrate 100 firstly, and depositing a light shielding material thin film on the base substrate 100; performing a patterning process on the light shielding material thin film to form a light shielding layer 600; depositing an insulation material thin film on the light shielding layer 600 to form a buffer layer 110; depositing a semiconductor material thin film on the buffer layer 110, and patterning the semiconductor material thin film to form a semiconductor layer 201; later, sequentially depositing a gate insulation material thin film 121, a conductive material thin film 410a, and a photoresist 800 on the semiconductor layer 201.

For example, the material of the gate insulation material thin film 121 is silicon oxide, and the thickness of the gate insulation material thin film 121 ranges from 0.1 to 0.2 microns. For example, the material of the conductive material thin film 410a is copper, and the thickness of the conductive material thin film 410a is about 0.4 microns.

For example, the base substrate 100 may be a rigid substrate; or the base substrate 100 can be a flexible substrate such that the array substrate including the thin film transistor can be applied in a field of flexible display. For example, the material of the base substrate 100 may be a glass substrate, a quartz substrate, or a resin-based material. For example, the resin-based material includes any one or any combination of polyimide, polycarbonate, polyacrylate, polyetherimide, polyethersulfone, polyethylene terephthalate, polyethylene naphthalate, and the like.

For example, in at least one embodiment of the present disclosure, the patterning process may be a photolithographic patterning process, for example, the patterning process may include: coating a photoresist on a structural layer to be patterned, exposing the photoresist using a mask, developing the exposed photoresist to obtain a photoresist pattern, etching the structural layer by taking the photoresist pattern as a mask, and then optionally removing the photoresist pattern. It should be noted that if the structural layer to be patterned includes a photoresist material, the process of coating photoresist is not necessary.

As illustrated in FIG. 4A-FIG. 4B, the photoresist 800 is patterned by a halftone mask to form a first photoresist pattern 810, the first photoresist pattern 810 includes a second portion 812 and first portions 811 at two sides of the second portion 812, and the thickness of the first portion 811 is smaller than the thickness of the second portion 812. For example, the thickness of the first portion 811 is about 0.5 microns and the thickness of the second portion 812 is about 2.2 microns.

As illustrated in FIG. 4B-FIG. 4C, the conductive material thin film 410a is patterned by using the first photoresist pattern 810 as a mask. The portion of the conductive material thin film 410a that is not covered by the first photoresist pattern 810 is removed, and the remaining conductive material thin film 410a forms the first conductive layer 410.

For example, the conductive material thin film 410a may be wet-etched using a hydrogen peroxide (H₂O₂) chemical solution. It should be noted that, in the actual process, the film thickness of the conductive material thin film formed by deposition may be not uniform. In order to ensure that the portion of the conductive material thin film 410a not covered by the first photoresist pattern 810 is completely removed, the etching time may be increased according to actual needs, that is, during the wet-etching process, an over Etch (OE) may be performed, and the OE amount may be selected according to the actual process. For example, the OE amount may range from 20% to 60%, for example, 30%, 40%, 50%, or the like. Illustratively, in the case where the design thickness of the conductive material thin film is 400 nm, and it takes 60 seconds to remove a portion of the conductive material thin film having a thickness of 400 nm using hydrogen peroxide (H₂O₂). In the actual process, the conductive material thin film is etched by hydrogen peroxide (H₂O₂) for 84 seconds, and the portion of the conductive material thin film not covered by the first photoresist pattern can be completely removed, and in this case, the OE amount is 40%.

As illustrated in FIG. 4C-FIG. 4D, the gate insulation material thin film 121 is patterned by using the first photoresist pattern 810 and the first conductive layer 410 as a mask. The portion of the gate insulation material thin film 121 that is not covered by the first photoresist pattern 810 and the first conductive layer 410 is removed, and the remaining gate insulation material thin film 121 forms the gate insulation layer 120.

For example, the gate insulation material thin film 121 may be dry-etched using a mixed gas including a high content of carbon tetrafluoride (CF4) and a low content of oxygen.

As illustrated in FIG. 4D-FIG. 4E, the semiconductor layer 201 is subjected to a treatment for forming a conductor by taking the gate insulation layer 120, the first conductive layer 410, and the first photoresist pattern 810 as a mask. For example, a portion of the semiconductor layer 201 that is not covered by the first conductive layer 410 is ion-doped such that the portion of the semiconductor layer 201 that is not covered by the first conductive layer 410 forms conductorized regions 220, and the portion of the semiconductor layer 201 that is not converted into a conductor forms a channel region 210.

As illustrated in FIG. 4E-FIG. 4F, performing a thickness reduction process to the first photoresist pattern 810 to remove the first portion 811 and reduce the thickness of the portion of the first conductive layer 410 which overlaps the first portion 811 (that is, the portion of the first conductive layer 410 that is not covered by the photoresist pattern after the first portion 811 is removed). For example, the first photoresist pattern 810 is subjected to an ashing process, the ashing time is controlled such that the first portion 811 is removed and the thickness of the second portion 812 is reduced, and the second portion 812 that is thinned forms a second photoresist pattern 820. For example, the ashing time may be about 80 seconds, and the photoresist (first photoresist pattern 810) having a thickness of about 0.5 microns can be removed. For example, the ashing process may be performed in an ICP (inductively coupled plasma) dry etching apparatus. For example, the first conductive layer 410 is etched by using the second photoresist pattern 820 as a mask, and the etching time is controlled such that the portion of the first conductive layer 410 that is not covered by the second photoresist pattern 820 is thinned. Illustratively, the first conductive layer 410 (for example, copper) having a thickness of about 400 nm is etched using the hydrogen peroxide chemical solution, and the total wet etching time required for completely etching is about 75 seconds. In an actual process, the etching time may be designed to be about 80% of the total wet etching time, so that the thickness of the portion of the first conductive layer 410 not covered by the second photoresist pattern 820 is reduced to about ⅕ of the original thickness, that is, the actual etching time was 60 seconds, and the thickness of the portion, which is thinned, of the first conductive layer 410 is about 80 nm.

As illustrated in FIG. 4F-FIG. 4G, the first conductive layer 410 is oxidized by an oxygen ion implantation or an oxygen implantation, the portion of the first conductive layer 410 not covered by the second photoresist pattern 820 is oxidized to form a light shielding portion 500, and the portion of the first conductive layer 410 covered by the second photoresist pattern 820 is not oxidized and forms the gate electrode 400. After the gate electrode 400 and the light shielding portion 500 are formed, the second photoresist pattern 820 is removed.

As illustrated in FIG. 4H, an insulation material thin film is deposited on the side of the gate electrode 400 and the light shielding portion 500 away from the base substrate 100 to form an interlayer dielectric layer 130, and a patterning process is performed on the interlayer dielectric layer 130 to form via-holes 131 in the interlayer dielectric layer 130, and the via-holes 131 expose the conductorized regions 220 of the active layer 200. For example, the via-holes 131 may be formed in the interlayer dielectric layer 130 by dry etching.

As illustrated in FIG. 4H and FIG. 2, a conductive material thin film is deposited on the interlayer dielectric layer 130, and a patterning process is performed on the conductive material thin film to form a source electrode 310 and a drain electrode 320. The source electrode 310 and the drain electrode 320 electrically connect (or directly in contact) to the conductorized regions 220 of the active layer 200 through via-holes 131. For example, an insulation material thin film is deposited on the source electrode 310 and the drain electrode 320 to form a passivation layer 140.

For example, in at least one embodiment of the present disclosure, the source electrode and the drain electrode may include a metal material, and may be formed to be a single layer structure or a multilayer structure, for example, a single-layer aluminum structure, a single-layer molybdenum structure, or a three-layer structure in which a molybdenum layer is sandwiched between two molybdenum layers. For example, the thickness of the source electrode and the drain electrodes may range from 0.5 to 0.7 microns.

For the present disclosure, the following statements should be noted:

(1) The accompanying drawings only involve the structure(s) in connection with the embodiment(s) of the present disclosure, and other structure(s) can be referred to common design(s).

(2) For clarity, in the accompanying drawings of the embodiment(s) of the present disclosure, the thickness and size of a layer or a structure may be enlarged or reduced. That is, the accompanying drawings are not drawn according to actual scales.

(3) The embodiments of the present disclosure and the features in the embodiment(s) may be combined in case of no conflict.

The described above are only specific embodiments of the present disclosure, and the present disclosure is not limited thereto. The scope of the present disclosure is defined by the accompanying claims.

What is claimed is:

1. A thin film transistor, comprising:
an active layer;
a source electrode and a drain electrode that electrically connect to the active layer, respectively;
a gate electrode and a light shielding portion that are on same one side of the active layer,
wherein in a direction from the source electrode to the drain electrode, the gate electrode is between the source electrode and the drain electrode; and
the light shielding portion is at at least one of a group consisting of a spacing between the gate electrode and the source electrode and a spacing between the gate electrode and the drain electrode.

2. The thin film transistor according to claim 1, wherein the light shielding portion is made of an insulation material.

3. The thin film transistor according to claim 1, wherein the light shielding portion is formed through oxidization of a local region of a film layer that has same one material as the gate electrode.

4. The thin film transistor according to claim 3, wherein in a direction perpendicular to a plane on which the active layer is located, a thickness of the light shielding portion is smaller than a thickness of the gate electrode.

5. The thin film transistor according to claim 1, wherein in a direction that is parallel to a plane on which the active layer is located and along the direction from the source electrode to the drain electrode, a width of the light shielding portion ranges from ¼ to ½ of a width of the gate electrode.

6. The thin film transistor according to claim 1, wherein the gate electrode comprises a metal material, and the light shielding portion comprises a metal oxide corresponding to the metal material.

7. The thin film transistor according to claim 6, wherein the gate electrode comprises a copper or a copper alloy, and the metal oxide comprises a copper oxide; or,
the gate electrode comprises a silver or a silver alloy, and the metal oxide comprises a silver oxide.

8. The thin film transistor according to claim 1, wherein the active layer comprises a channel region and two conductorized regions respectively at two sides of the channel region; and
the source electrode and the drain electrode electrically connect to the two conductorized regions, respectively.

9. The thin film transistor according to claim 8, wherein an orthographic projection of a combination structure of the gate electrode and the light shielding portion on a plane on which the active layer is located overlaps with an orthographic projection of the channel region on the plane on which the active layer is located.

10. The thin film transistor according to claim 9, further comprising a light shielding layer on a side, which is away from the gate electrode, of the active layer,
wherein the orthographic projection of the channel region of the active layer on the plane on which the active layer is located overlaps with an orthographic projection of the light shielding layer on the plane on which the active layer is located.

11. The thin film transistor according to claim 9, further comprising a gate insulation layer between the active layer and the gate electrode,
wherein the orthographic projection of the combination structure of the gate electrode and the light shielding portion on the plane on which the active layer is located overlaps with an orthographic projection of the gate insulation layer on the plane on which the active layer is located.

12. The thin film transistor according to claim 1, further comprising a gate insulation layer located between the active layer and the gate electrode,
wherein an orthographic projection of a combination structure of the gate electrode and the light shielding portion on a plane on which the active layer is located overlaps with an orthographic projection of the gate insulation layer on a plane on which the active layer is located.

13. An array substrate, comprising a thin film transistor, wherein the thin film transistor comprises an active layer, a source electrode, a drain electrode, a gate electrode and a light shielding portion;
the source electrode and the drain electrode electrically connect to the active layer, respectively;
the gate electrode and the light shielding portion are on same one side of the active layer;
in a direction from the source electrode to the drain electrode, the gate electrode is between the source electrode and the drain electrode; and
the light shielding portion is at at least one of a group consisting of a spacing between the gate electrode and the source electrode and a spacing between the gate electrode and the drain electrode.

14. A manufacturing method of a thin film transistor, comprising:
forming an active layer;
forming a gate electrode and a light shielding portion on same one side of the active layer; and
forming a source electrode and a drain electrode that electrically connect to the active layer, respectively;
wherein in a direction from the source electrode to the drain electrode, the gate electrode is formed between the source electrode and the drain electrode; and
the light shielding portion is formed at at least one of a group consisting of a spacing between the gate electrode and the source electrode and a spacing between the gate electrode and the drain electrode.

15. The manufacturing method according to claim 14, wherein a material of the light shielding portion is an insulation material.

16. The manufacturing method according to claim 14, wherein the gate electrode and the light shielding portion are formed from a same film layer by performing a light shielding treatment on the same film layer.

17. The manufacturing method according to claim 16, wherein forming of the gate electrode and the light shielding portion comprises:
forming a conductive material thin film and forming a photoresist layer on the conductive material thin film;
patterning the photoresist layer to form a first photoresist pattern, and patterning the conductive material thin film by taking the first photoresist pattern as a first mask, so as to form a first conductive layer;
removing a portion of the first photoresist pattern to form a second photoresist pattern and allowing a side edge of the first conductive layer to be exposed;
performing an oxidizing treatment to the first conductive layer, wherein the side edge, that is not covered by the second photoresist pattern, of the first conductive layer is oxidized and forms the light shielding portion, and a portion, which is not oxidized, of the first conductive layer forms the gate electrode; and
removing the second photoresist pattern.

18. The manufacturing method according to claim 17, wherein forming of the gate electrode and the light shielding portion further comprises:
processing the photoresist layer with a halftone mask to allow the first photoresist pattern to comprises a first portion and a second portion, wherein a thickness of the first portion is smaller than a thickness of the second portion; and
performing a thickness reduction process on the first photoresist pattern to remove a portion of the first photoresist pattern, wherein the first portion is removed to allow a portion, which overlaps the first portion, of the first conductive layer to be exposed after the first portion is removed and to be thinned, and the second portion forms the second photoresist pattern.

19. The manufacturing method according to claim 18, wherein a material used to form the first conductive layer comprises a metal material; and
performing of the oxidizing treatment to the first conductive layer comprises:
oxidizing a portion, that is not covered by the second photoresist pattern, of the first conductive layer to form a metal oxide by an oxygen ion implantation or an oxygen implantation.

20. The manufacturing method according to claim 17, further comprising:
forming an insulation material thin film on a side of the active layer before forming the conductive material thin film; and
patterning the insulation material film to form the gate insulation layer by taking the first photoresist pattern and the first conductive layer as a second mask, wherein an orthographic projection of the first conductive layer on a plane on which the active layer is located overlaps with an orthographic projection of the gate insulation layer on the plane on which the active layer is located.
